(19) United States
(12) Patent Application Publication
(10) Pub. No.: US 2026/0173460 A1
(43) Pub. Date: Jun. 18, 2026

(54) SEMICONDUCTOR MEMORY DEVICE AND MANUFACTURING METHOD THEREOF

(71) Applicant: SK hynix Inc., Gyeonggi-do (KR)

(72) Inventors: Jae Wook YANG, Gyeonggi-do (KR); Nam Cheol JEON, Gyeonggi-do (KR)

(21) Appl. No.: 19/250,079

(22) Filed: Jun. 26, 2025

(30) Foreign Application Priority Data
Dec. 18, 2024 (KR) 10-2024-0189784

(51) Int. Cl. H10D 30/69; G11C 16/04; H10B 43/27; H10B 43/35; H10D 30/01; H10D 62/83

(52) U.S. Cl. CPC H10D 30/693; G11C 16/0483; H10B 43/27; H10B 43/35; H10D 30/0413; H10D 62/83

(57) ABSTRACT

The embodiments of the present disclosure relate to a semiconductor memory device and a method of manufacturing the semiconductor memory device. The semiconductor memory device includes a stack structure including interlayer insulating layers and conductive patterns which are stacked alternately, and channel structures disposed to penetrate the stack structure. Each of the channel structures includes a doped semiconductor pattern disposed at a core of each channel structure with a level to at least partially overlap with at least one upper conductive pattern among the conductive patterns, a vertical channel layer including a first region disposed to surround the doped semiconductor pattern and a second region disposed to extend below the first region, and a memory layer disposed to surround the vertical channel layer, wherein a thickness of the first region is thicker than a thickness of the second region.

### CROSS-REFERENCE TO RELATED APPLICATION

The present application claims priority under 35 U.S.C. § 119(a) to Korean patent application number 10-2024-0189784 filed on Dec. 18, 2024, the entire disclosure of which is incorporated by reference herein.

### BACKGROUND

### 1. Technical Field

Various embodiments of the present disclosure relate generally to a semiconductor memory device and a manufacturing method thereof, and more particularly, to a three-dimensional semiconductor memory device and a manufacturing method thereof.

### 2. Related Art

Semiconductor memory devices store data under the control of host devices such as computers and smartphones. Semiconductor memory devices are divided into volatile memory devices and non-volatile memory devices.

Volatile memory devices store data only when power is supplied, and the stored data disappears when the power supply is cut off. Volatile memory devices include static random access memory (SRAM), dynamic random access memory (DRAM), and the like.

Non-volatile memory devices are memory devices in which data does not disappear even when power is cut off, such as Read Only Memory (ROM), Programmable ROM (PROM), Electrically Programmable Rom (EPROM), Electrically Erasable and Programmable Rom (EEPROM), and Flash Memory.

Semiconductor memory devices include memory cells capable of storing data. A three-dimensional semiconductor memory device includes memory cells arranged in three dimensions, so that the area occupied by the memory cells per unit area of a substrate may be reduced.

To improve the degree of integration of the three-dimensional semiconductor memory device, the number of stacked memory cells may be increased. As the number of stacked memory cells increases, the operational reliability of the three-dimensional semiconductor memory device may decrease.

### SUMMARY

Embodiments of the present disclosure are directed to a semiconductor memory device capable of improving operational reliability, and a method of manufacturing the same.

According to an embodiment of the present disclosure, a semiconductor memory device may include a stack structure including interlayer insulating layers and conductive patterns which are stacked alternately, and channel structures disposed to penetrate the stack structure. Each of the channel structures includes a doped semiconductor pattern disposed in a core of each channel structure with a level to at least partially overlap with at least one upper conductive pattern among the conductive patterns, a vertical channel layer including a first region disposed to surround a sidewall of the doped semiconductor pattern and a second region disposed to extend below the first region, and a memory layer disposed to surround the vertical channel layer, wherein a thickness of the first region is greater than a thickness of the second region.

According to an embodiment of the present disclosure, a semiconductor memory device may include a stack structure including interlayer insulating layers and conductive patterns which are stacked alternately, and channel structures penetrating the stack structure. Each of the channel structures includes a core insulating layer disposed at a core of each channel structure to extend in a vertical direction, a doped semiconductor pattern disposed on the core insulating layer and disposed at a level to at least partially overlap with at least one upper conductive pattern among the conductive patterns, a vertical channel layer disposed to extend in the vertical direction to surround the core insulating layer and the doped semiconductor pattern, and a memory layer disposed to extend in the vertical direction to surround the vertical channel layer, wherein the vertical channel layer surrounding the doped semiconductor pattern includes a first channel layer and a second channel layer.

According to an embodiment of the present disclosure, a method of manufacturing a semiconductor memory device may include forming a stack structure including interlayer insulating layers and sacrificial layers which are stacked alternately, forming a channel hole penetrating through the stack structure, forming a memory layer extending along a sidewall of the channel hole, forming a first channel layer extending on a surface of the memory layer, forming a core insulating layer on a surface of the first channel layer to fill the channel hole, etching back the core insulating layer to expose the first channel layer on top of the channel hole, forming a second channel layer on the exposed first channel layer, and forming a doped semiconductor pattern to fill the channel hole.

### BRIEF DESCRIPTION OF THE DRAWINGS

FIG. 1 is a block diagram illustrating a semiconductor memory device according to an embodiment of the present disclosure;

FIG. 2 is a circuit diagram illustrating a memory block according to an embodiment of the present disclosure;

FIGS. 3A and 3B are perspective views schematically illustrating semiconductor memory devices according to embodiments of the present disclosure;

FIG. 4 is a perspective view illustrating gate stacks of a semiconductor memory device according to an embodiment of the present disclosure;

FIG. 5 is an enlarged cross-sectional view of an area A shown in FIG. 4, according to an embodiment of the present disclosure;

FIG. 6 is a cross-sectional view showing a source layer and a channel structure according to an embodiment of the present disclosure;

FIG. 7 is a cross-sectional view showing a source layer and a channel structure according to an embodiment of the present disclosure;

FIGS. 8A to 8C, 9A to 9D, and 10A to 10C are cross-sectional views illustrating a method of manufacturing a memory cell array according to an embodiment of the present disclosure;

FIG. 11 is a block diagram illustrating a memory system including a semiconductor memory device of FIG. 1, according to an embodiment of the present disclosure;

FIG. 12 is a block diagram illustrating an application example of a memory system of FIG. 11, according to an embodiment of the present disclosure; and

FIG. 13 is a block diagram illustrating a computing system including a memory system described with reference to FIG. 12, according to an embodiment of the present disclosure.

### DETAILED DESCRIPTION

Specific structural or functional descriptions of embodiments in accordance with concepts which are disclosed in this specification are illustrated only to describe the embodiments which may be carried out in various forms. However, the descriptions are not limited to the embodiments described in this specification and include modifications of the described embodiments.

While terms such as “first” and “second” may be used to describe various components, such components must not be understood as being limited to the above terms. The above terminologies are used to distinguish one component from the other component, for example, a first component may be referred to as a second component without departing from a scope in accordance with the concept of the present disclosure and similarly, a second component may be referred to as a first component.

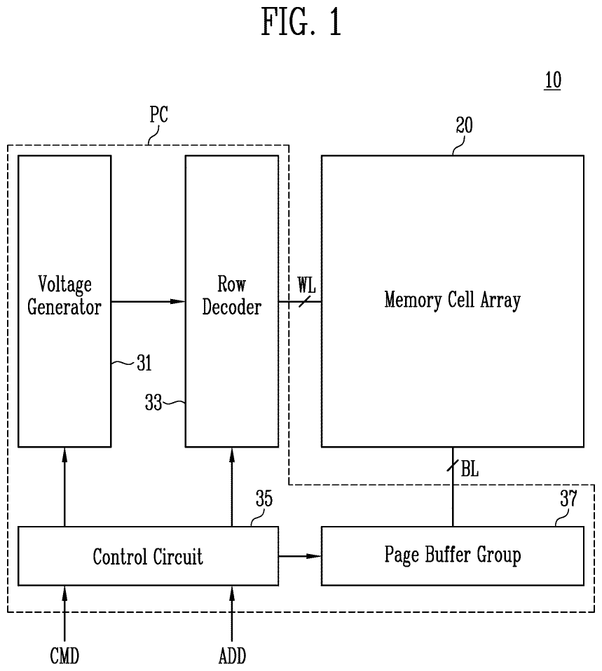

FIG. 1 is a block diagram illustrating a semiconductor memory device 10 according to an embodiment of the present disclosure.

Referring to FIG. 1, the semiconductor memory device 10 includes a peripheral circuit PC and a memory cell array 20.

The peripheral circuit PC may control a program operation to store data in the memory cell array 20, a read operation to output data stored in the memory cell array 20, and an erase operation to erase data stored in the memory cell array 20.

In an embodiment, the peripheral circuit PC may include a voltage generator 31, a row decoder 33, a control circuit 35, and a page buffer group 37.

The memory cell array 20 may include a plurality of memory blocks. The memory cell array 20 may be coupled to the row decoder 33 via word lines WL, and may be coupled to the page buffer group 37 via bit lines BL.

The control circuit 35 may control the peripheral circuit PC in response to a command CMD and an address ADD.

The voltage generator 31 may generate various operating voltages such as a pre-erase voltage, an erase voltage, a ground voltage, a program voltage, a verify voltage, a pass voltage, and a read voltage, which are used for a program operation, a read operation, and an erase operation, in response to the control of the control circuit 35.

The row decoder 33 may select a memory block in response to the control of the control circuit 35. The row decoder 33 may apply operating voltages to the word lines WL coupled to the selected memory block.

The page buffer group 37 may be coupled to the memory cell array 20 via the bit lines BL. The page buffer group 37 may temporarily store data received from an input/output circuit (not shown) during a program operation in response to control of the control circuit 35. The page buffer group 37 may sense voltages or currents of the bit lines BL during a read operation or a verify operation in response to control of the control circuit 35. The page buffer group 37 may select the bit lines BL in response to control of the control circuit 35.

Structurally, the memory cell array 20 may overlap with a portion of the peripheral circuit PC.

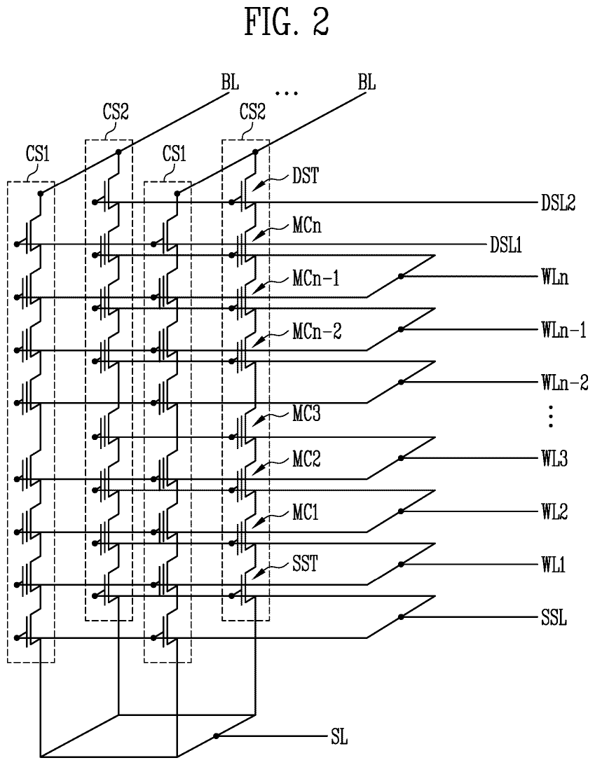

FIG. 2 is a circuit diagram illustrating a memory block according to an embodiment of the present disclosure.

Referring to FIG. 2, the memory block may include a source layer SL and a plurality of cell strings CS1 and CS2 commonly coupled to a plurality of word lines WL1 to WLn. The plurality of cell strings CS1 and CS2 may be coupled to the plurality of bit lines BL.

Each of the plurality of cell strings CS1 and CS2 may include at least one source select transistor SST coupled to the source layer SL, at least one drain select transistor DST coupled to the bit line BL, and a plurality of memory cells MC1 to MCn coupled in series between the source select transistor SST and the drain select transistor DST.

Gates of the plurality of memory cells MC1 to MCn may be respectively coupled to the plurality of word lines WL1 to WLn stacked apart from each other. The plurality of word lines WL1 to WLn may be arranged between a source select line SSL and two or more drain select lines DSL1 and DSL2. The two or more drain select lines DSL1 and DSL2 may be spaced apart from each other at the same level.

A gate of the source select transistor SST may be coupled to the source select line SSL. A gate of the drain select transistor DST may be coupled to a drain select line corresponding to the gate of the drain select transistor DST.

The source layer SL may be coupled to a source of the source select transistor SST. A drain of the drain select transistor DST may be coupled to a bit line corresponding to the drain of the drain selecting transistor DST.

The plurality of cell strings CS1 and CS2 may be divided into string groups coupled to each of the two or more drain select lines DSL1 and DSL2. Cell strings coupled to the same word line and the same bit line may be independently controlled by different drain select lines. Further, cell strings coupled to the same drain select line may be independently controlled by different bit lines.

In an embodiment, the two or more drain select lines DSL1 and DSL2 may include a first drain select line DSL1 and a second drain select line DSL2. The plurality of cell strings CS1 and CS2 may include a first cell string CS1 of a first string group coupled to the first drain select line DSL1 and a second cell string CS2 of a second string group coupled to the second drain select line DLS2.

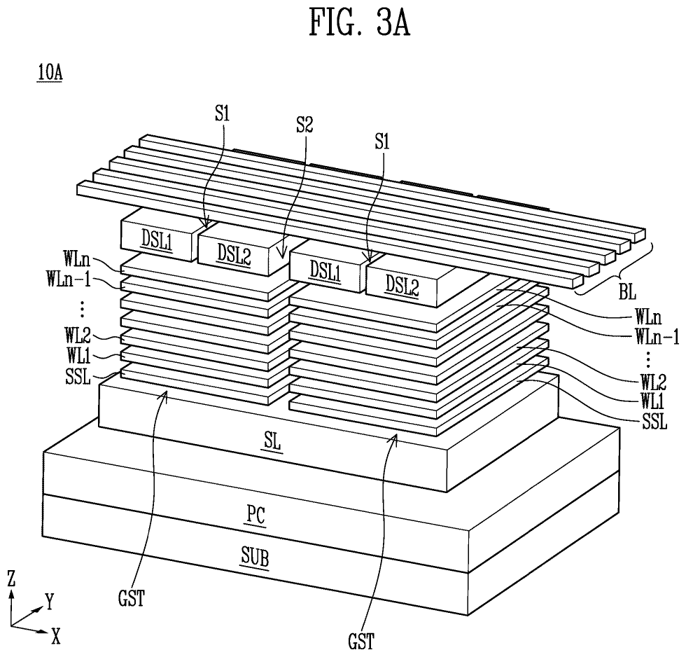

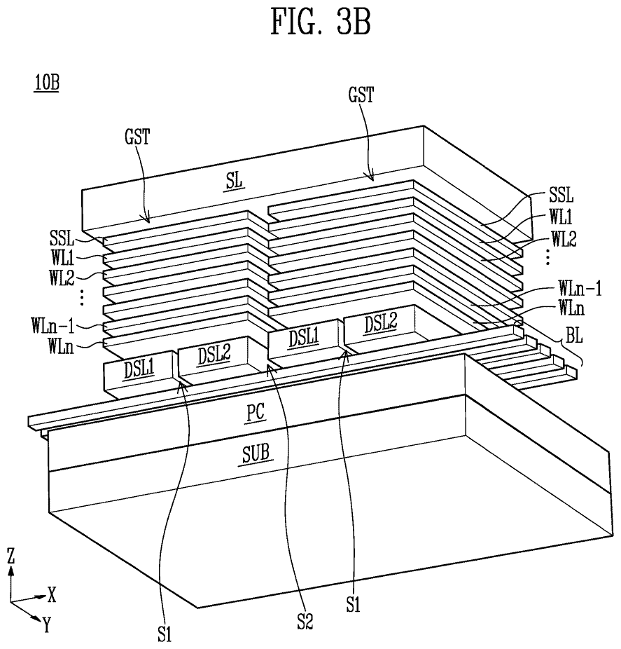

FIGS. 3A and 3B are perspective views schematically illustrating semiconductor memory devices 10A and 10B according to embodiments of the present disclosure.

Referring to FIGS. 3A and 3B, each of the semiconductor memory devices 10A and 10B may include the peripheral circuit PC arranged on a substrate SUB and gate stacks GST superimposed on the peripheral circuit PC.

Each of the gate stacks GST may include the source select line SSL, the plurality of word lines WL1 to WLn, and the two or more drain select lines DSL1 and DSL2 separated from each other at the same level by a first slit S1.

The source select line SSL and the plurality of word lines WL1 to WLn extend in a first direction X and a second direction Y, and may be formed in a flat plate shape parallel to the upper surface of the substrate SUB. The first direction X may be a direction toward an X-axis of an XYZ coordinate system, and the second direction Y may be a direction towards a Y-axis of the XYZ coordinate system.

The plurality of word lines WL1 to WLn may be stacked apart from each other in a third direction Z. The third direction Z may be a direction toward a Z-axis of the XYZ coordinate system. The plurality of word lines WL1 to WLn may be arranged between the two or more drain select lines DSL1 and DSL2 and the source select line SSL.

The gate stacks GST may be separated from one another by a second slit S2. The first slit S1 is formed shorter than the second slit S2 in the third direction Z and may overlap with the plurality of word lines WL1 to WLn.

Each of the first slit S1 and the second slit S2 may extend in a straight, zigzag, or wave-like pattern. The width of each of the first slit S1 and the second slit S2 may be variously changed according to design rules.

Referring to FIG. 3A, the source select line SSL according to an embodiment may be arranged closer to the peripheral circuit PC than the two or more drain select lines DSL1 and DSL2.

The semiconductor memory device 10A may include the source layer SL arranged between the gate stacks GST and the peripheral circuit PC, and the plurality of bit lines BL spaced further from the peripheral circuit PC than the source layer SL. The gate stacks GST may be arranged between the plurality of bit lines BL and the source layer SL.

Referring to FIG. 3B, the two or more drain select lines DSL1 and DSL2 according to an embodiment may be arranged closer to the peripheral circuit PC than the source select line SSL.

The semiconductor memory device 10B may include the plurality of bit lines BL arranged between the gate stacks GST and the peripheral circuit PC, and the source layer SL spaced further from the peripheral circuit PC than the plurality of bit lines BL. The gate stacks GST may be arranged between the plurality of bit lines BL and the source layer SL.

Referring again to FIGS. 3A and 3B, the plurality of bit lines BL may include various conductive materials. The source layer SL may include a doped semiconductor layer. In an embodiment, the source layer SL may include an n-type doped silicon layer.

Although not shown in FIGS. 3A and 3B, the peripheral circuit PC may be electrically coupled to the plurality of bit lines BL, the source layer SL, and the plurality of word lines WL1 to WLn through interconnections with various structures.

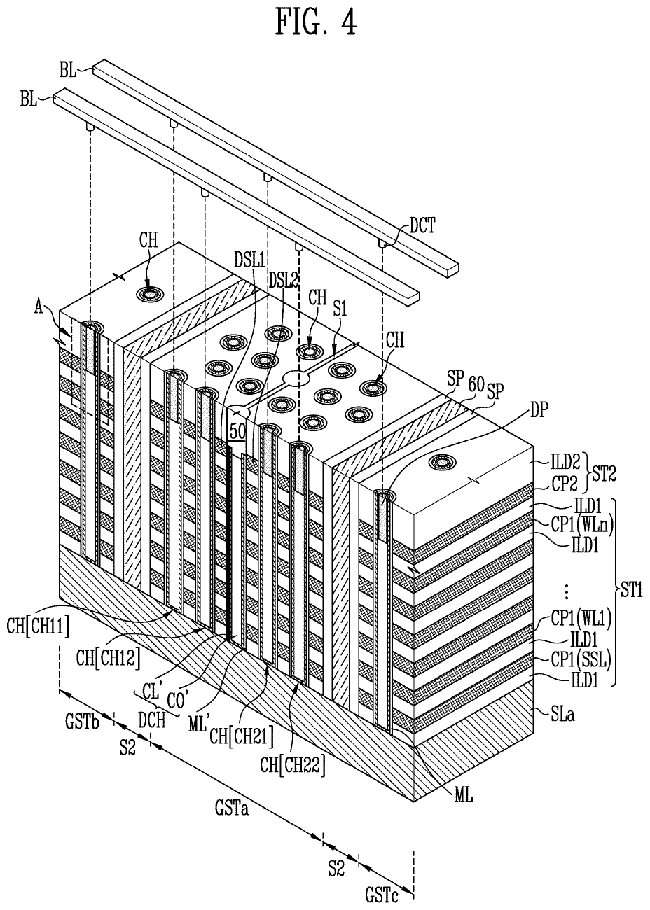

FIG. 4 is a perspective view illustrating gate stacks GSTa, GSTb, and GSTc of a semiconductor memory device according to an embodiment of the present disclosure.

Referring to FIG. 4, each of the gate stacks GSTa, GSTb, and GSTc may include a first stack ST1 and a second stack ST2. The first stack ST1 and the second stack ST2 may be arranged between the plurality of bit lines BL and a source layer SLa.

The plurality of bit lines BL may overlap with the first stack ST1, and the second stack ST2 may be arranged between the first stack ST1 and the plurality of bit lines BL. The plurality of bit lines BL may overlap with the source layer SLa.

The first stack ST1 may include first interlayer insulating layers ILD1 and first conductive patterns CP1 which are alternately stacked with each other. The first conductive patterns CP1 may serve as the source select line SSL and the plurality of word lines WL1 to WLn.

The second stack ST2 may include a second conductive pattern CP2 and a second interlayer insulating layer ILD2. The second conductive pattern CP2 may be arranged between the first interlayer insulating layers ILD1 and the second interlayer insulating layer ILD2 arranged on the first stack ST1. The second conductive pattern CP2 and the second interlayer insulating layer ILD2 may be sequentially arranged on the first stack ST1 to overlap with the first stack ST1. The second conductive pattern CP2 may serve as the drain select lines DSL1 and DSL2.

The second stack ST2 may be penetrated by the first slit S1. The second conductive pattern CP2 of the second stack ST2 may be separated into the drain select lines DSL1 and DSL2 by the first slit S1. In an embodiment, each of the gate stacks GSTa, GSTb, and GSTc may include the first drain select line DSL1 and the second drain select line DSL2 separated by the first slit S1.

The gate stacks GSTa, GSTb, and GSTc may be separated from one another by second slits S2 formed deeper than the first slit S1. A spacer insulating layer SP may be formed on a sidewall of each of the second slits S2, and a vertical structure 60 may be formed in each of the second slits S2. In an embodiment, the vertical structure 60 may include a conductive material which contacts the source layer SLa and fills the inside of each of the second slits S2. However, the embodiments of the present disclosure are not limited thereto. In one embodiment, the vertical structure 60 may include insulation.

The first stack ST1 and the second stack ST2 of each of the gate stacks GSTa, GSTb, and GSTc may be penetrated by a plurality of channel structures CH. The plurality of channel structures CH may be arranged in a plurality of channel columns. The channel structures CH arranged in each channel column may include channel structures arranged in a line in a direction in which the bit lines BL extend. In an embodiment, the channel structures CH arranged in each channel column may include first channel structures CH11 and CH12 and second channel structures CH21 and CH22. The first channel structures CH11 and CH12 may be arranged on one side of the first slit S1, and the second channel structures CH21 and CH22 may be arranged on the other side of the first slit S1. The first slit S1 may be arranged between the first channel structures CH11 and CH12 and the second channel structures CH21 and CH22.

In an embodiment, the first channel structures CH11 and CH12 may extend through the first drain select line DSL1 and the first stack ST1. The second channel structures CH21 and CH22 may extend through the second drain select line DSL2 and the first stack ST1. Each of the second conductive pattern CP2, the second interlayer insulating layer ILD2, the first conductive patterns CP1, and the first interlayer insulating layers ILD1 may extend to surround the first channel structures CH11 and CH12 and the second channel structures CH21 and CH22.

Each of the bit lines BL may be electrically coupled to one of the first channel structures CH11 and CH12 and to one of the second channel structures CH21 and CH22 via drain contact plugs DCT.

A dummy channel structure DCH may be arranged between the first channel structures CH11 and CH12 and the second channel structures CH21 and CH22. The dummy channel structure DCH may penetrate the first stack ST1. The first slit S1 may overlap with the dummy channel structure DCH.

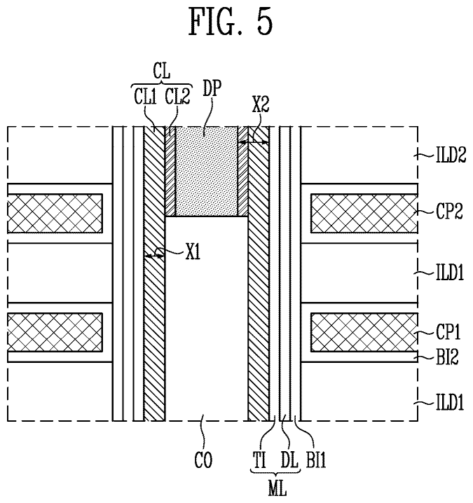

Each of the channel structures CH may include a core insulating layer CO, a doped semiconductor pattern DP, and a (vertical) channel layer CL (see FIG. 5). The dummy channel structure DCH may include a dummy core insulating layer CO′ and a dummy channel layer CL′.

The core insulating layer CO may be arranged vertically at a center (i.e., a core) of each of the channel structures CH, and may be surrounded by the first stack ST1. The doped semiconductor pattern DP may overlap with the core insulating layer CO and be surrounded by the second conductive pattern CP2 and the second interlayer insulating layer ILD2. In an embodiment, the doped semiconductor pattern DP may include an n-type doped silicon layer. The channel layer CL may extend along a sidewall of the core insulating layer CO and a sidewall of the doped semiconductor pattern DP. That is, the channel layer CL may surround the sidewall of the core insulating layer CO and the sidewall of the doped semiconductor pattern DP.

A thickness of a first region of the channel layer CL which surrounds the sidewall of the doped semiconductor pattern DP may be greater than a thickness of a second region of the channel layer CL which surrounds the sidewall of the core insulating layer CO. The second region of the channel layer CL extends below the first region. For example, the first region of the channel layer CL which surrounds the sidewall of the doped semiconductor pattern DP may have a multilayer structure, and the second region of the channel layer CL which surrounds the sidewall of the core insulating layer CO may have a single-layer structure. One end of the channel layer CL may be coupled to one of the bit lines BL through a contact plug DCT. One end of the channel layer CL may directly contact the contact plug DCT. The other end of the channel layer CL extends between the source layer SLa and the core insulating layer CO, and may contact the source layer SLa. In an embodiment, each of the channel layer CL and the dummy channel layer CL′ may include an undoped silicon layer.

A dummy memory layer ML′ may extend on a sidewall of an isolation insulating layer 50. The isolation insulating layer 50 may be arranged between the first drain select line DSL1 and the second drain select line DSL2. The isolation insulating layer 50 may fill the first slit S1 and overlap with the dummy channel structure DCH. The dummy memory layer ML′ may include the same material layers as a memory layer ML.

Although not shown in FIG. 4, an upper insulating layer penetrated by the contact plug DCT may be arranged between the plurality of bit lines BL and the second stack ST2.

A sidewall of each of the channel structures CH may be surrounded by the memory layer ML. A sidewall of the dummy channel structure DCH may be surrounded by the dummy memory layer ML′.

The first region of the channel layer CL which surrounds the doped semiconductor pattern DP has a greater thickness than the second region thereof which surrounds the core insulating layer CO. That is, a thickness of a region of the channel layer CL which is adjacent to the second conductive pattern CP2 has a relatively large thickness, so that a junction overlap region may be easily secured in a channel under the drain select transistor. In addition, since the doped semiconductor pattern DP may be surrounded by at least a part of the second conductive pattern CP2, a junction overlap region may be easily secured in a channel under the drain select transistor. Therefore, a gate induced drain leakage (GIDL) current generated in a lower channel of the drain select transistor may be increased during an erase operation of the semiconductor memory device. The GIDL current may be generated by a difference between an erase voltage applied to the bit lines BL and a gate voltage applied to the second conductive pattern CP2.

A first blocking layer (not shown) may be arranged between the first stack ST1 and the memory layer ML and between the second conductive pattern CP2 and the memory layer ML.

FIG. 5 is an enlarged cross-sectional view of an area A shown in FIG. 4.

Referring to FIG. 5, the memory layer ML may include a tunnel isolation layer TI and a data storage layer DL. The tunnel isolation layer TI may surround a sidewall of the channel layer CL. The tunnel isolation layer TI may include an insulating material capable of charge tunneling. In an embodiment, the tunnel isolation layer TI may include a silicon oxide layer. The data storage layer DL may surround a sidewall of the tunnel isolation layer TI. The data storage layer DL may include a material layer capable of storing data. The data storage layer DL may include a nitride layer capable of charge trapping. However, the embodiments are not limited thereto, and the data storage layer DL may include a phase change material, nanodots, or the like.

The memory layer ML may extend to heights of the sidewalls of the first interlayer insulating layers ILD1 and the first conductive patterns CP1, and heights of the sidewalls of the second conductive pattern CP2 and the second interlayer insulating layer ILD2.

The channel layer CL may surround the sidewall of the core insulating layer CO and the sidewall of the doped semiconductor pattern DP. The channel layer CL may overlap with a sidewall of the second conductive pattern CP2.

In an embodiment, a second thickness X2 of the channel layer CL surrounding the sidewall of the doped semiconductor pattern DP may be thicker than the first thickness X1 of the channel layer CL surrounding the sidewall of the core insulating layer CO. The channel layer CL may include a first channel layer CL1 and a second channel layer CL2. The first channel layer CL1 may extend along an inner sidewall of the memory layer ML, and the first channel layer CL1 may surround the sidewall of the core insulating layer CO and the sidewall of the doped semiconductor pattern DP. The first channel layer CL1 may directly contact an outer wall of the core insulating layer CO. The second channel layer CL2 may surround the sidewall of the doped semiconductor pattern DP. The second channel layer CL2 may contact a part of an inner wall of the first channel layer CL1. The second channel layer CL2 may be arranged between a part of the inner wall of the first channel layer CL1 and an outer wall of the doped semiconductor pattern DP. The second channel layer CL2 may be disposed with a level to at least partially overlap with the sidewall of the second conductive pattern CP2. The channel layer CL overlapping with the sidewall the second conductive pattern CP2 includes the first channel layer CL1 and the second channel layer CL2, so that a sufficient thickness may be ensured.

A first blocking insulating layer BI1 may surround a sidewall of the data storage layer DL. The first blocking insulating layer BI1 may extend along the sidewall of the doped semiconductor pattern DP. The first blocking insulating layer BI1 may be arranged along the sidewalls of the first conductive patterns CP1, the first interlayer insulating layers ILD1, the second conductive pattern CP2, and the second interlayer insulating layer ILD2. The first blocking insulating layer BI1 may include an oxide.

The first conductive patterns CP1 may surround the memory layer ML between the first interlayer insulating layers ILD1. The first conductive patterns CP1 may include a conductive material having a lower resistance than silicon. In an embodiment, the first conductive patterns CP1 may include a metal layer.

A second blocking insulating layer BI2 may be further formed between the first conductive pattern CP1 and the first blocking insulating layer BI1. The second blocking insulating layer BI2 may include an insulating material having a higher dielectric constant than that of the first blocking insulating layer BI1. In an embodiment, the second blocking insulating layer BI2 may include a metal oxide layer. In an embodiment, the metal oxide may include an aluminum oxide layer. The second blocking insulating layer BI2 may extend along an interface between the first conductive patterns CP1 and the first interlayer insulating layers ILD1.

The second conductive pattern CP2 may surround the memory layer ML between the first interlayer insulating layer ILD1 and the second interlayer insulating layer IL2. In addition, the second conductive pattern CP2 may include the doped semiconductor pattern DP, the first channel layer CL1, and the second channel layer CL2 between the first interlayer insulating layer ILD1 and the second interlayer insulating layer IL2 so as to surround the channel layer CL. For example, a lower end of the sidewall of the second conductive pattern CP2 may surround the first channel layer CL1, and an upper end of the sidewall of the second conductive pattern CP2 may surround both the first channel layer CL1 and the second channel layer CL2. That is, the first channel layer CL1 and the second channel layer CL2 may overlap with the upper end of the sidewall of the second conductive pattern CP2. In another embodiment, the first channel layer CL1 and the second channel layer CL2 may overlap with the entire sidewall of the second conductive pattern CP2.

The second conductive pattern CP2 may serve as the drain select line DSL coupled to the gate of the drain select transistor DST as shown in FIG. 2.

The semiconductor memory devices shown in FIGS. 4 and 5 may be applied to the semiconductor memory device 10A shown in FIG. 3A. The semiconductor memory device as shown in FIGS. 4 and 5 may be inverted and applied to the semiconductor memory device 10B as shown in FIG. 3B.

The channel layer CL may include a bottom surface which penetrates the memory layer ML and contacts the source layer SLa, as shown in FIG. 4. Embodiments of the present disclosure are not limited thereto.

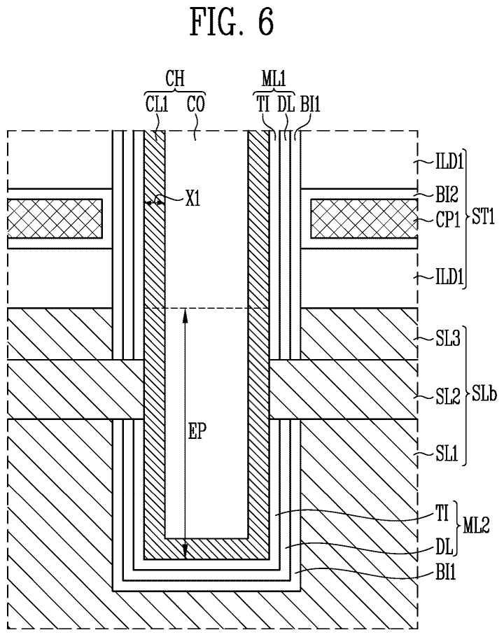

FIG. 6 is a cross-sectional view showing a source layer SLb and the channel structure CH according to an embodiment of the present disclosure. The structure shown in FIG. 6 may be applied to the semiconductor memory device 10A shown in FIG. 3A.

Referring to FIG. 6, the source layer SLb may include a first layer SL1 and a second layer SL2, or may include the first layer SL1, the second layer SL2, and a third layer SL3. The first layer SL1 may overlap with the first stack ST1. The second layer SL2 may be arranged between the first stack ST1 and the first layer SL1. The third layer SL3 may be arranged between the second layer SL2 and the first stack ST1.

Each of the first layer SL1, the second layer SL2, and the third layer SL3 may include a doped semiconductor layer. In an embodiment, each of the first layer SL1, the second layer SL2, and the third layer SL3 may include n-type doped silicon.

The first stack ST1 may include the first interlayer insulating layers ILD1 and the first conductive patterns CP1 alternately stacked as described with reference to FIG. 4, and may be penetrated by the channel structure CH.

An end portion EP of the channel structure CH passes through the third layer SL3 and the second layer SL2, and may extend into the first layer SL1. In an embodiment, the first channel layer CL1 and the core insulating layer CO may penetrate the third layer SL3 and the second layer SL2 and extend into the first layer SL1.

Each of the data storage layer DL and the tunnel isolation layer TI may be separated into a first memory pattern ML1 and a second memory pattern ML2 by the second layer SL2. The second layer SL2 protrudes toward the first channel layer CL1 more than the first layer SL1 and the third layer SL3, and may contact the first channel layer CL1. The first blocking insulating layer BI1 may be arranged to contact a sidewall of the first memory pattern ML1. That is, the first blocking insulating layer BI1 may be arranged between the sidewall of the first memory pattern ML1 and the sidewalls of the third layer SL3, the first interlayer insulating layers ILD1, and the first conductive patterns CP1. In addition, the first blocking insulating layer BI1 may be arranged to contact a sidewall and a lower surface of the second memory pattern ML2. That is, the first blocking insulating layer BI1 may be arranged between the sidewall and the lower surface of the second memory pattern ML2 and a sidewall and a lower surface of the first layer SL1.

The first blocking insulating layer BI1, the data storage layer DL, and the tunnel isolation layer TI may extend from between the first stack ST1 and the first channel layer CL1 to between the third layer SL3 and the first channel layer CL1. The first blocking insulating layer BI1, the data storage layer DL, and the tunnel isolation layer TI of the second memory pattern ML2 may extend between the first layer SL1 and the first channel layer CL1.

The second blocking insulating layer BI2 may be arranged between the first blocking insulating layer BI1 of the first memory pattern ML1 and the first conductive pattern CP1.

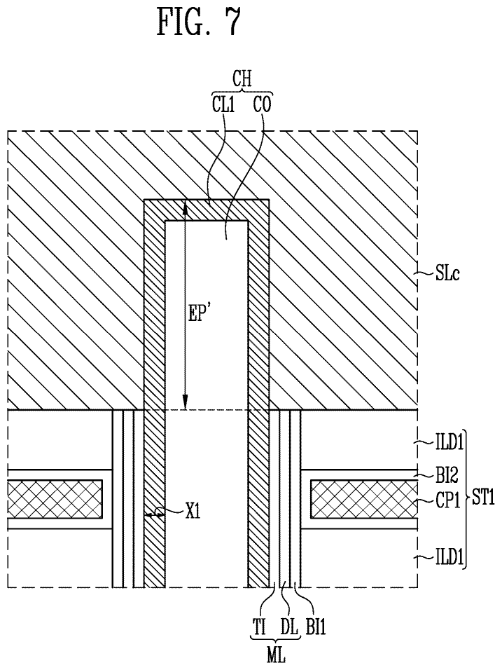

FIG. 7 is a cross-sectional view showing a source layer SLc and the channel structure CH according to an embodiment of the present disclosure. The structure shown in FIG. 7 may be applied to the semiconductor memory device 10B shown in FIG. 3B.

Referring to FIG. 7, the source layer SLc may overlap with the first stack ST1 and include a doped semiconductor layer. In an embodiment, the source layer SLc may include n-type doped silicon. The first stack ST1 may be arranged between the source layer SLc and the second stack ST2 as described with reference to FIG. 4.

The first stack ST1 may include the first interlayer insulating layers ILD1 and the first conductive patterns CP1 alternately stacked as described with reference to FIG. 4, and may be penetrated by the channel structure CH.

The end portion EP′ of the channel structure CH may penetrate the first blocking insulating layer BI1, the data storage layer DL of the memory layer ML, and the tunnel isolation layer TI and may extend into the source layer SLc. In an embodiment, the first channel layer CL1 and the core insulating layer CO may extend into the source layer SLc. A part of the first channel layer CL1 constituting the end portion EP′ of the channel structure CH may contact the source layer SLc.

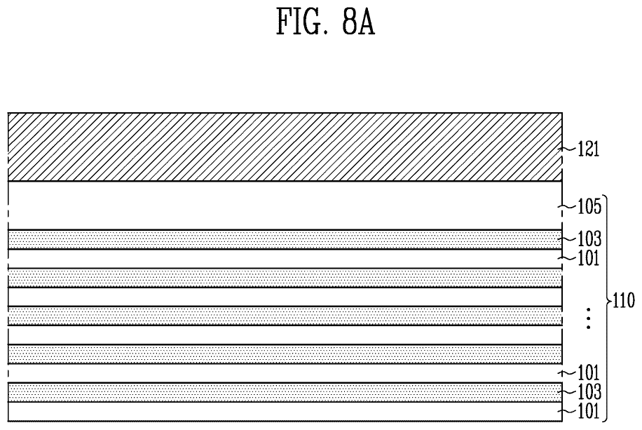

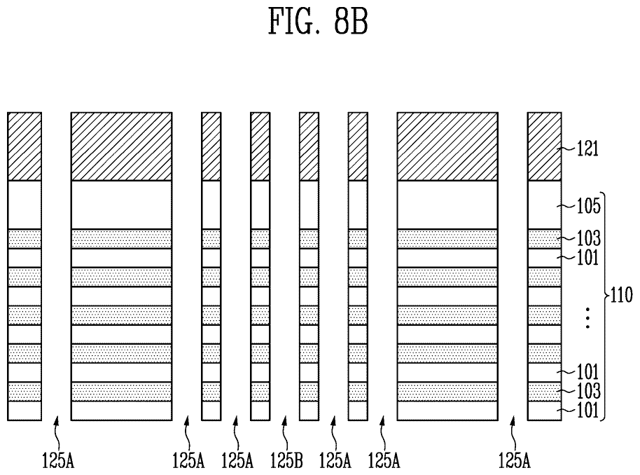

FIGS. 8A to 8C, 9A to 9D, and 10A to 10C are cross-sectional views illustrating a method of manufacturing a memory cell array according to an embodiment of the present disclosure.

FIGS. 8A to 8C are cross-sectional views illustrating a process of forming a preliminary stack 110 and a process of forming preliminary channel structures penetrating the preliminary stack 110 and each surrounded by the memory layer ML.

Referring to FIG. 8A, the process of forming the preliminary stack 110 may include alternately stacking first interlayer insulating layers 101 and sacrificial layers 103. Each of the sacrificial layers 103 may include a material having an etching selectivity for the first interlayer insulating layers 101. In an embodiment, the first interlayer insulating layers 101 may include silicon oxide, and the sacrificial layers 103 may include silicon nitride. Subsequently, a second interlayer insulating layer 105 is formed on the uppermost sacrificial layer 103. For example, the first interlayer insulating layers 101 and the sacrificial layers 103 are alternately stacked on a semiconductor substrate, and the second interlayer insulating layer 105 is stacked on the uppermost sacrificial layer 103 to thereby form the preliminary stack 110.

Subsequently, a mask layer 121 is formed over the preliminary stack 110. The mask layer 121 may include a nitride layer.

Referring to FIG. 8B, channel holes 125A may be formed by etching the mask layer 121 and the preliminary stack 110. The channel holes 125A may penetrate the preliminary stack 110. During the process of forming the channel holes 125A, a dummy hole 125B penetrating the preliminary stack 110 may be formed simultaneously with the channel holes 125A.

The channel holes 125A and the dummy hole 125B may be defined by etching the mask layer 121 and the preliminary stack 110 using a photoresist pattern (not shown) formed through a photolithography process as an etching barrier. After the channel holes 125A and the dummy hole 125B are formed, the photoresist pattern may be removed.

Referring to FIG. 8C, the memory layer ML covering surfaces of the channel holes and the dummy hole and extending onto a surface of the mask layer 121 may be formed. The memory layer ML may include a data storage layer and a tunnel isolation layer. Thereafter, the first channel layer CL1 may be formed on the surface of the memory layer ML.

After the first channel layer CL1 is formed, central regions of the channel holes and the dummy hole may be filled with the core insulating layer CO.

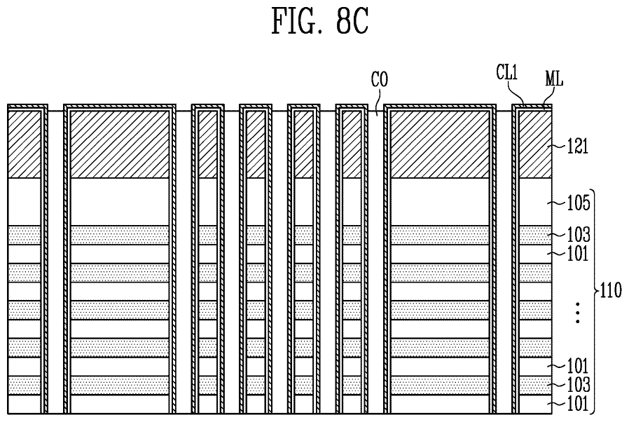

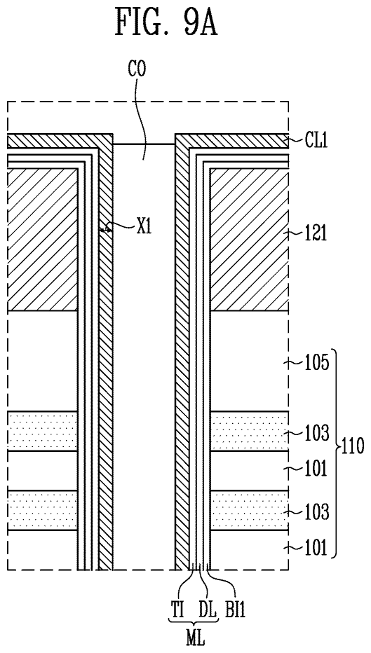

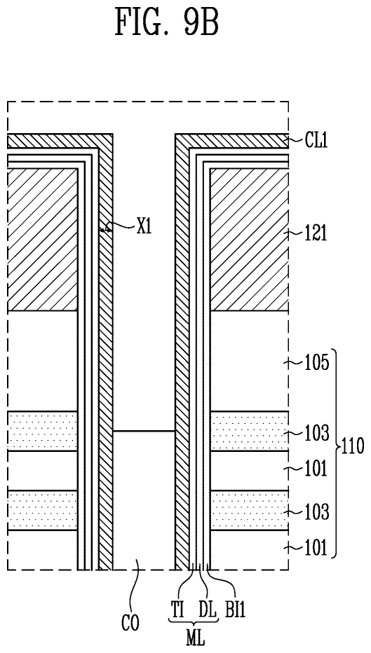

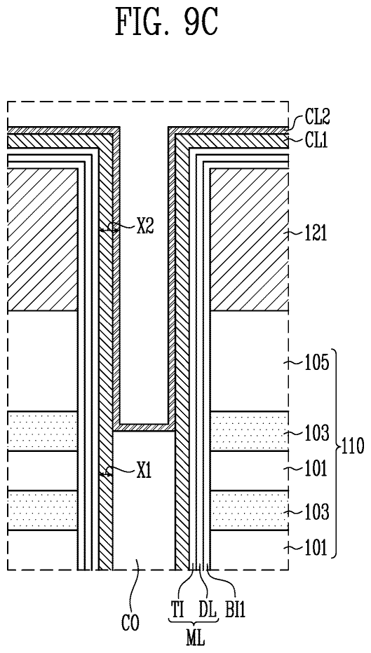

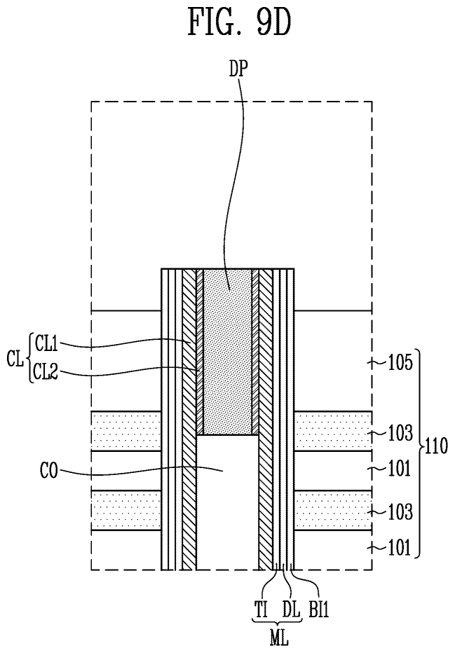

FIGS. 9A to 9D are enlarged cross-sectional views showing an embodiment of a process of forming the memory layer ML, the first channel layer CL1, the second channel layer CL2, the core insulating layer CO, and the doped semiconductor pattern DP in the channel hole.

Referring to FIG. 9A, the process of forming the memory layer ML, the first channel layer CL1, and the core insulating layer CO as shown in FIG. 8C may include forming the first blocking insulating layer BI1 on a surface of each of the channel holes and the dummy hole. The first blocking insulating layer BI1 may include an oxide.

Thereafter, the data storage layer DL and the tunnel isolation layer TI may be sequentially formed on the surface of the first blocking insulating layer BI1 to form the memory layer ML. The tunnel isolation layer TI may include an insulating material capable of charge tunneling. In an embodiment, the tunnel isolation layer TI may include a silicon oxide layer. The data storage layer DL may include a material layer capable of storing data. The data storage layer DL may include a nitride layer capable of charge trapping. However, the embodiments of the present disclosure are not limited thereto, and the data storage layer DL may include a phase change material, nanodots, or the like.

Subsequently, the first channel layer CL1 may be formed on the surface of the tunnel isolation layer TI. The first channel layer CL1 may include a silicon layer.

Subsequently, the core insulating layer CO may be formed on the surface of the first channel layer CL1, and may be formed such that the inside of the channel hole is filled by the core insulating layer CO. The core insulating layer CO may be formed by depositing an oxide layer by an ALD method. Thereafter, an etch-back process may be performed on the core insulating layer CO so that the core insulating layer CO remains only in the channel hole.

Referring to FIG. 9B, the core insulating layer CO may be etched by a dry etch process so that an upper surface of the core insulating layer CO may be located at a position lower than an upper surface of at least one sacrificial layer 103 located at the top among the sacrificial layers 103 by performing an etch process. For example, the upper surface of the core insulating layer CO may be located at a position higher than a sacrificial layer corresponding to a word line among the sacrificial layers 103.

Referring to FIG. 9C, the second channel layer CL2 may be in the form of a liner on a sidewall surface of the first channel layer CL1 and the upper surface of the core insulating layer CO. The second channel layer CL2 may include a silicon layer. The second channel layer CL2 may include the same material as the first channel layer CL1.

Referring to FIG. 9D, a doped semiconductor layer is deposited in a space where the core insulating layer CO is etched, and a planarization etch process is performed so that the mask layer may be exposed to form the doped semiconductor pattern DP on the top of the core insulating layer CO.

In this manner, the channel layer CL including the second channel layer CL2 and the first channel layer CL1 may surround the sidewall of the doped semiconductor pattern DP, and the sidewall of the core insulating layer CO may surround the first channel layer CL1.

By the planarization etch process as described above, the memory layer ML, the first channel layer CL1, the second channel layer CL2, and the doped semiconductor pattern DP may protrude partly higher than the upper surface of the second interlayer insulating layer 105.

The doped semiconductor pattern DP is formed on an upper sidewall portion of the sacrificial layer 103 located at the top with the first blocking insulating layer BI1 interposed therebetween.

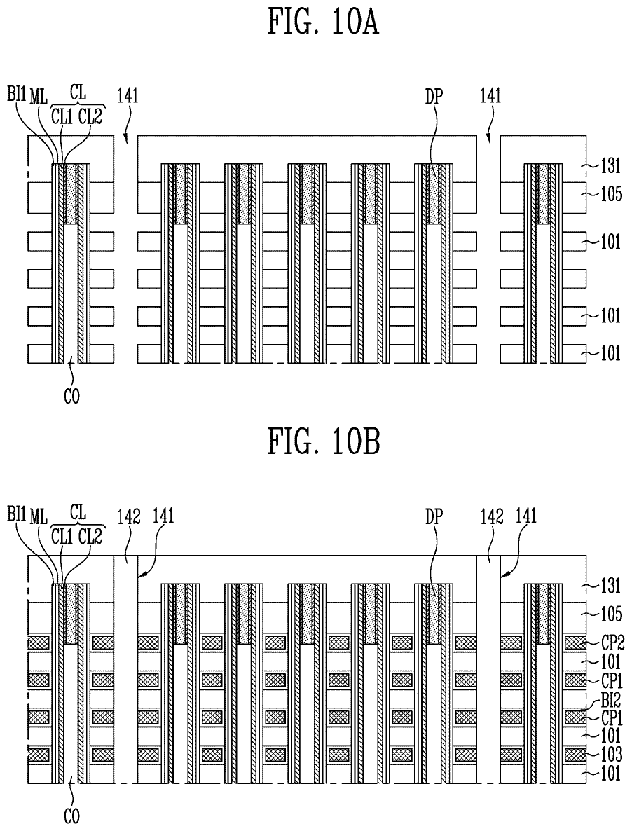

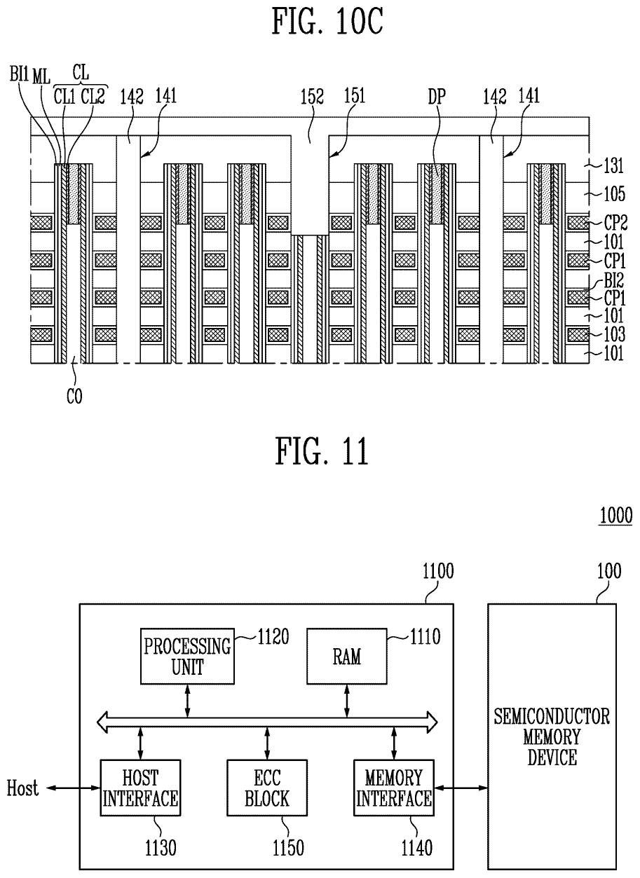

FIGS. 10A to 10C illustrate an embodiment of a process of forming first conductive patterns and second conductive patterns in a space between the first interlayer insulating layers 101.

Referring to FIG. 10A, a slit-forming mask layer 131 is formed over the entire structure including the doped semiconductor pattern DP after the process shown in FIG. 9D. Subsequently, an etch process using the slit-forming mask layer 131 is performed to sequentially etch the second interlayer insulating layer 105 and the sacrificial layers and the first interlayer insulating layers 101 stacked alternately with each other to form a second slit 141. Subsequently, the sacrificial layers exposed through the second slit 141 are removed. As a result, an empty space is formed between the first interlayer insulating layers 101 and between the first interlayer insulation layer 101 and the second interlayer insulation layer 105.

Referring to FIG. 10B, a conductive material is filled in the empty space between the first interlayer insulating layers 101 and between the first interlayer insulation layer 101 and the second interlayer insulating layer 105 to form the first conductive patterns CP1 and the second conductive pattern CP2. The first conductive patterns CP1 and the second conductive pattern CP2 may include a conductive material having a lower resistance than silicon. In an embodiment, the first conductive patterns CP1 and the second conductive pattern CP2 may include a metal layer. The first conductive patterns CP1 are formed in spaces between the first interlayer insulating layers 101, and the second conductive pattern CP2 is formed in a space between the first interlayer insulation layer 101 at the top and the second interlayer insulation layer 105.

The second blocking insulating layer BI2 may be formed on the surface of the empty space before the first conductive patterns CP1 and the second conductive pattern CP2 are formed. The second blocking insulating layer BI2 may include an insulating material having a higher dielectric constant than that of the first blocking insulating layer BI1. In an embodiment, the second blocking insulating layer BI2 may include an aluminum oxide layer.

Referring to FIG. 10C, the second slit 141 is filled with an insulating material 142. A first slit 151 is then formed on top of a dummy channel structure. The first slit 151 may be formed in a line shape, and the second conductive pattern CP2 surrounding the dummy channel structure is separated at both ends by the first slit 151. Subsequently, the first slit 151 is filled with an insulating material 152.

FIG. 11 is a diagram illustrating a memory system 1000 including the semiconductor memory device 10 of FIG. 1, according to an embodiment of the present disclosure.

Referring to FIG. 11, the memory system 1000 may include a semiconductor memory device 100 and a controller 1100. The semiconductor memory device 100 may be the semiconductor memory device 10 which is described above with reference to FIG. 1.

The controller 1100 may be coupled to a host and the semiconductor memory device 100. In response to a request from the host, the controller 1100 may access the memory device. For example, the controller 1100 may control write, read, erase, and background operations of the memory device. The controller 1100 may provide an interface between the semiconductor memory device 100 and the host. The controller 1100 may drive firmware for controlling the semiconductor memory device 100.

The controller 1100 may include a random access memory (RAM) 1110, a processing unit 1120, a host interface 1130, a memory interface 1140, and an error correction code (ECC) block 1150. The RAM 1110 may serve as at least one of a working memory, a cache memory between the semiconductor memory device 100 and the host, and a buffer memory between the semiconductor memory device 100 and the host. The processing unit 1120 may control overall operations of the controller 1100. In addition, the controller 1100 may temporarily store program data provided from the host during a write operation.

The host interface 1130 may include a protocol for exchanging data between the host 2000 and the controller 1100. According to an embodiment, the controller 1100 may communicate with the host 2000 through one or more various communication interfaces or standards such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, a private protocol, etc.

The memory interface 1140 may interface with the semiconductor memory device 100. For example, the memory interface 1140 may include a NAND interface or a NOR interface.

The ECC block 1150 may be configured to detect and correct an error in data receive from the semiconductor memory device 100. The processing unit 1120 may control the semiconductor memory device 100 to control a read voltage according to an error detection result and perform re-read. According to an embodiment, the ECC block 1150 may be provided as a component of the controller 1100.

The controller 1100 and the semiconductor memory device 100 may be integrated into a single semiconductor device to form a memory card. For example, the controller 1100 and the semiconductor memory device 100 may be integrated into a single semiconductor device and form a memory card, such as a personal computer memory card international association (PCMCIA), a compact flash (CF) card, a smart media card (SM or SMC), a memory stick multimedia card (MMC, RS-MMC, or MMCmicro), an SD card (SD, miniSD, microSD, or SDHC), a universal flash storage (UFS), and the like.

The controller 1100 and the semiconductor memory device 100 may be integrated into a single semiconductor device to form a solid state drive (SSD). The SSD may include a storage device that is configured to store data in a semiconductor memory. When the memory system 1000 serves as the SSD, an operating speed of the host coupled to the memory system 1000 may be remarkably improved.

In another embodiment, the memory system 1000 may be provided as one of various elements of an electronic device such as a computer, an ultra mobile PC (UMPC), a workstation, a net-book, a personal digital assistant (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, or the like.

In an embodiment, the semiconductor memory device 100 or the memory system 1000 may be mounted in packages in various forms. For example, the semiconductor memory device 100 or the memory system 1000 may be embedded in packages such as a package on package (PoP), ball grid arrays (BGAs), chip scale packages (CSPs), a plastic leaded chip carrier (PLCC), a plastic dual in line package (PDIP), a die in waffle pack, a die in wafer form, a chip on board (COB), a ceramic dual in line package (CERDIP), a plastic metric quad flat pack (MQFP), a thin quad flatpack (TQFP), a small outline integrated circuit (SOIC) package, a shrink small outline package (SSOP), a thin small outline package (TSOP), a system in package (SIP), a multichip package (MCP), a wafer-level fabricated package (WFP), a wafer-level processed stack package (WSP), or the like.

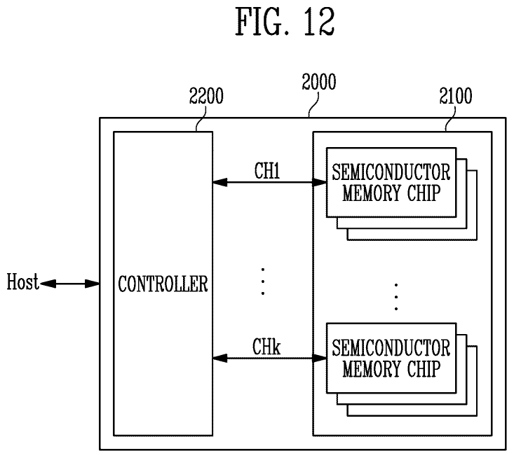

FIG. 12 is a block diagram illustrating an application of the memory system 1000 of FIG. 11, according to an embodiment of the present disclosure.

Referring to FIG. 12, a memory system 2000 may include a semiconductor memory device 2100 and a controller 2200. The semiconductor memory device 2100 may include semiconductor memory chips. The semiconductor memory chips may be divided into a plurality of groups.

FIG. 12 illustrates the groups communicating with the controller 2200 through first to k-th channels CH1 to CHk. Each of the semiconductor memory chips may be configured and operated in substantially the same manner as the semiconductor memory device 10 described above with reference to FIG. 1.

Each group may communicate with the controller 2200 through a single common channel. The controller 2200 may be configured in substantially the same manner as the controller 1100 described with reference to FIG. 11, and configured to control the plurality of memory chips of the semiconductor memory device 2100 through the plurality of channels CH1 to CHk.

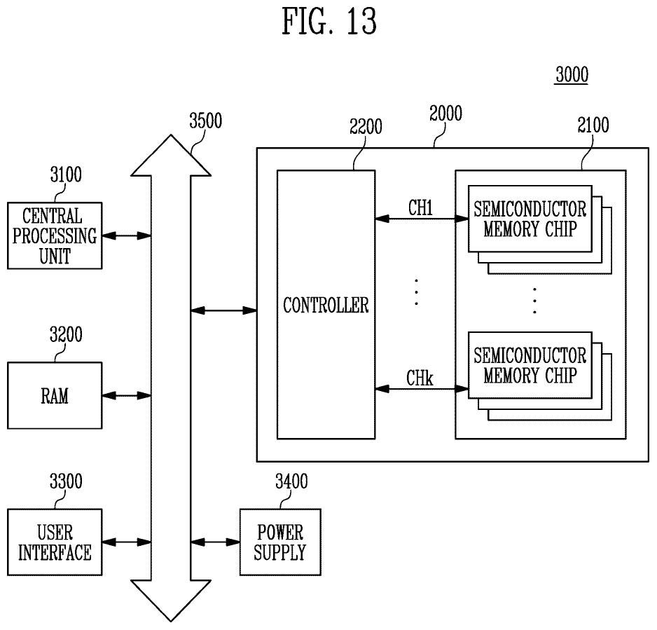

FIG. 13 is a block diagram illustrating a computing system 3000 including the memory system 2000 described above with reference to FIG. 12, according to an embodiment of the present disclosure.

The computing system 3000 may include a central processing unit 3100, a random access memory (RAM) 3200, a user interface 3300, a power supply 3400, a system bus 3500, and the memory system 2000.

The memory system 2000 may be electrically connected to the central processing unit 3100, the RAM 3200, the user interface 3300 and the power supply 3400 through the system bus 3500. Data provided through the user interface 3300 or processed by the central processing unit 3100 may be stored in the memory system 2000.

As shown in FIG. 13, the semiconductor memory device 2100 may be coupled to the system bus 3500 through the controller 2200. However, the semiconductor memory device 2100 may be directly coupled to the system bus 3500. The central processing unit 3100 and the RAM 3200 may perform functions of the controller 2200.

As illustrated in FIG. 13, the memory system 2000 shown in FIG. 12 may be provided. However, the memory system 2000 may be replaced by the memory system 1000 shown in FIG. 11. According to an embodiment, the computing system 3000 may include both of the memory systems 1000 and 2000 described above with reference to FIGS. 11 and 12.

According to the embodiments of the present disclosure, characteristics of a drain select transistor may be improved to stably generate a gate induced drain leakage (GIDL) current for an erase operation, thereby improving the operational reliability of a semiconductor memory device.

While the embodiments of the present disclosure have been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor memory device comprising:
a stack structure including interlayer insulating layers and conductive patterns which are stacked alternately; and
channel structures disposed to penetrate the stack structure,
wherein each of the channel structures comprises:
a doped semiconductor pattern disposed at a core of each channel structure with a level to at least partially overlap with at least one upper conductive pattern among the conductive patterns;
a vertical channel layer including a first region disposed to surround the doped semiconductor pattern and a second region disposed to extend below the first region; and
a memory layer disposed to surround the channel layer, and
wherein a thickness of the first region is thicker than a thickness of the second region.

2. The semiconductor memory device of claim 1, wherein each of the channel structures further comprises a core insulating layer arranged under the doped semiconductor pattern.

3. The semiconductor memory device of claim 2, wherein the second region of the vertical channel layer is disposed to surround the core insulating layer.

4. The semiconductor memory device of claim 1, wherein the first region of the channel layer at least partially overlaps with a sidewall of the at least one upper conductive pattern.

5. The semiconductor memory device of claim 1, further comprising a first blocking insulating layer disposed to surround the memory layer.

6. The semiconductor memory device of claim 1, wherein the at least one upper conductive pattern includes a drain select line corresponding to a drain select transistor included in a cell string.

7. The semiconductor memory device of claim 1, wherein:
the doped semiconductor pattern includes an n-type doped silicon layer; and
the vertical channel layer includes an undoped silicon layer.

8. The semiconductor memory device of claim 2, wherein the first region of the vertical channel layer includes:
a first channel layer disposed to contact an inner wall of the memory layer; and
a second channel layer arranged between the first channel layer and the doped semiconductor pattern.

9. The semiconductor memory device of claim 8, wherein the second region of the vertical channel layer includes the second channel layer arranged between the memory layer and the core insulating layer.

10. A semiconductor memory device comprising:
a stack structure including interlayer insulating layers and conductive patterns which are stacked alternately; and
channel structures penetrating the stack structure,
wherein each of the channel structures comprises:
a core insulating layer disposed at a core of each channel structure to extend in a vertical direction;
a doped semiconductor pattern disposed on the core insulating layer and disposed at a level to at least partially overlap with at least one upper conductive pattern among the conductive patterns;
a vertical channel layer disposed to extend in the vertical direction to surround the core insulating layer and the doped semiconductor pattern; and
a memory layer disposed to extend in the vertical direction to surround the vertical channel layer, and
wherein the vertical channel layer surrounding the doped semiconductor pattern includes a first channel layer and a second channel layer.

11. The semiconductor memory device of claim 10, wherein the vertical channel layer surrounding the core insulating layer includes the first channel layer.

12. The semiconductor memory device of claim 10, wherein a thickness of a first region of the vertical channel layer surrounding the doped semiconductor pattern is thicker than a thickness of a second region of the vertical channel layer surrounding the core insulating layer.

13. The semiconductor memory device of claim 12, wherein the first region of the channel layer at least partially overlaps with the sidewall of the at least one upper conductive pattern.

14. The semiconductor memory device of claim 10, further comprising a first blocking insulating layer disposed to surround the memory layer.

15. The semiconductor memory device of claim 10, wherein the at least one upper conductive pattern includes a drain select line corresponding to a drain select transistor included in a cell string.

16. The semiconductor memory device of claim 10, wherein:
the doped semiconductor pattern includes an n-type doped silicon layer; and
the vertical channel layer includes an undoped silicon layer.

17. A method of manufacturing a semiconductor memory device, the method comprising:
forming a stack structure including interlayer insulating layers and sacrificial layers which are stacked alternately;
forming a channel hole penetrating through the stack structure;
forming a memory layer extending along a sidewall of the channel hole;
forming a first channel layer extending on a surface of the memory layer;
forming a core insulating layer on a surface of the first channel layer to fill the channel hole;
etching back the core insulating layer to expose the first channel layer on top of the channel hole;
forming a second channel layer on the exposed first channel layer; and
forming a doped semiconductor pattern to fill the channel hole.

18. The method of claim 17, wherein etching back the core insulating layer comprises etching the core insulating layer so that an upper surface of the core insulating layer has a level lower than at least a portion of at least one upper sacrificial layer among the sacrificial layers.

19. The method of claim 17, further comprising, before forming the memory layer, forming a blocking insulating layer extending along the sidewall of the channel hole.

20. The method of claim 17, further comprising:
forming a slit penetrating through the stack structure;
removing the sacrificial layers exposed through the slit; and
forming conductive patterns in spaces from which the sacrificial layers are removed.

21. The method of claim 20, wherein an upper conductive pattern among the conductive patterns is formed to at least partially overlap with the first channel layer and the second channel layer.
